(19) United States
(12) Patent Application Publication
(10) Pub. No.: US 2017/0213934 A1
(43) Pub. Date: Jul. 27, 2017

(54) HIGH-EFFICIENCY LIGHT EMITTING DIODE

(71) Applicant: Google Inc., Mountain View, CA (US)

(72) Inventors: Michael Grundmann, San Jose, CA (US); Martin F. Schubert, Mountain View, CA (US)

(21) Appl. No.: 15/005,872

(22) Filed: Jan. 25, 2016

(51) Int. Cl. H01L 33/00; H01L 33/30; H01L 27/15; H01L 33/42; H01L 33/24

(52) U.S. Cl. CPC H01L 33/0025; H01L 33/42; H01L 33/24; H01L 27/156; H01L 33/0062; H01L 33/30; H01L 2933/0016

(57) ABSTRACT

A light emitting diode (LED) includes a semiconductor material with an active region. The active region is disposed in the semiconductor material to produce light in response to a voltage applied across the semiconductor material. The active region includes a wide bandgap region disposed to inhibit charge transfer from a central region of the LED to the lateral edges of the LED. The active region also includes a narrow bandgap region disposed in the central region with the wide bandgap region disposed about the narrow bandgap region, and the narrow bandgap region has a narrower bandgap than the wide bandgap region.

### TECHNICAL FIELD

This disclosure relates generally to light emitting diodes, and in particular but not exclusively, relates to high-efficiency micro light emitting diodes.

### BACKGROUND INFORMATION

Light emitting diodes (LEDs) are semiconductor light emitters. In their simplest form, LEDs are a p-n junction that emits light when a voltage of sufficient magnitude is applied across the device. When the device is turned on, electrons combine with holes at the junction interface and release energy in the forms of light and heat. The color of the light (photon energy) is proportional to the size of the semiconductor bandgap and governed by the equation E=hv, where E is energy, h is Planck's constant, and v is the photon frequency.

Recently, LEDs have become ubiquitous and are used in a variety of applications including solid-state lighting, display technologies, and optical communications. The demands of lower power consumption and greater screen resolution have encouraged the miniaturization of these devices. State of the art screens may include many thousands of individual LED devices.

However, despite progress made in the diode field, there is still room for improvement. For instance, several colors of LED (e.g., green) exhibit relatively low quantum efficiency. Further, LED performance is tied to device dimensionality; therefore, device architecture may need to be altered depending on the scale of fabrication (e.g., millimeter, micron, or nanometer).

### BRIEF DESCRIPTION OF THE DRAWINGS

Non-limiting and non-exhaustive embodiments of the invention are described with reference to the following figures, wherein like reference numerals refer to like parts throughout the various views unless otherwise specified. The drawings are not necessarily to scale, emphasis instead being placed upon illustrating the principles being described.

FIG. 1 is a cross sectional illustration of a light emitting diode (LED), in accordance with an embodiment of the disclosure.

FIG. 2 is a functional block diagram illustrating a micro-LED display system, in accordance with an embodiment of the disclosure.

FIG. 3 is a flow chart describing a method of fabricating an LED, in accordance with several embodiments of the disclosure.

FIGS. 4A-4F illustrate a method of fabricating an LED, in accordance with an embodiment of the disclosure.

FIGS. 5A-5E illustrate a method of fabricating an LED, in accordance with an embodiment of the disclosure.

FIGS. 6A-6D illustrate a method of fabricating an LED, in accordance with an embodiment of the disclosure.

FIGS. 7A-7D illustrate a method of fabricating an LED, in accordance with an embodiment of the disclosure.

### DETAILED DESCRIPTION

Embodiments of an apparatus and method of fabrication for a high-efficiency light emitting diode are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

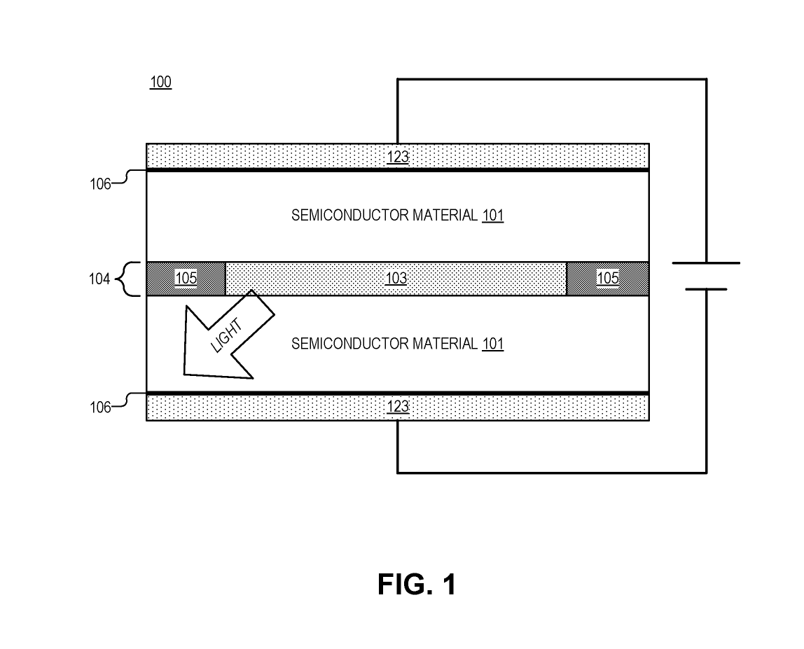

FIG. 1 is a cross sectional illustration of light emitting diode (LED) 100, in accordance with an embodiment of the disclosure. LED 100 includes: semiconductor material 101, active region 104, narrow bandgap region 103, wide bandgap region 105, and electrodes 123.

In the depicted embodiment, active region 104 is disposed in semiconductor material 101. Active region 104 includes wide bandgap region 105 disposed adjacent to the lateral edges of LED 100 to inhibit charge transfer from a central region of LED 100 to the lateral edges of LED 100. Narrow bandgap region 103 is disposed in the central region of LED 100 with wide bandgap region 105 disposed about narrow bandgap region 103, and narrow bandgap region 103 produces a substantial portion of the light. It is worth noting that narrow bandgap region 103 has a narrower bandgap than wide bandgap region 105. In one embodiment, wide bandgap region 105 and narrow bandgap region 103 have different elemental compositions and may include Al(GaIn)AsP or AlAs. Alternatively, wide bandgap region 105 and narrow bandgap region 103 may have the same elemental composition, but narrow bandgap region 103 has a higher density of states than wide bandgap region 105. In the depicted embodiment, semiconductor material 101 is disposed between first electrode 123 (top) and a second electrode 123 (bottom); however, in other embodiments, electrodes 123 may be disposed in other locations on the light emitting diode. In one or more embodiments, one or both of the electrodes 123 may be transparent.

Although not depicted in FIG. 1, LED 100 may include other pieces of device architecture. In one embodiment, active region 104 may include multiple wide bandgap regions 105 and multiple narrow bandgap regions 103 to form a multi-layer heterostructure with multiple quantum wells and barrier regions. In one embodiment, LED 100 may include hole or electron blocking layers 106 disposed between electrodes 123 and semiconductor material 101. Alternatively, hole or electron blocking layers 106 may be disposed in semiconductor material 101 proximate to active region 103. Additionally, semiconductor material 101 may include one or more semiconductor layers with differing elemental compositions. Further, other dopant elements may be added to semiconductor material 101 to form other structures including isolation regions. Oxide/polymer materials may also be used to isolate/encapsulate LED 100. In one embodiment, LED 100 is a micro-scale red LED.

In operation, LED 100 produces light when a voltage is applied across semiconductor material 101. Electrons injected through one of electrodes 123 travel through semiconductor material 101 and combine with holes, injected through the other electrode 123, in the active region 104. However, charge trapping and recombination at the surface of semiconductor LEDs may lead to appreciable decreases in quantum efficiency. Charge trapping and recombination may be the product of undesired interfacial chemical groups such as O—H groups, dangling bonds, etc., and may result in usable energy being converted into heat. This is particularly apparent in micro-scale devices—especially red emitting micro-scale devices—where charge carrier diffusion lengths approach the lateral dimensions of the device. Embodiments in accordance with the teaching of the present invention reduce surface charge trapping and recombination by preventing electrons/holes in semiconductor material 101 from reaching the surface of semiconductor material 101. Because wide bandgap region 105 presents a barrier to current flow, charge is directed towards the center (narrow bandgap region 103) of semiconductor material 101. This architecture promotes efficient photon emission from the center of the device.

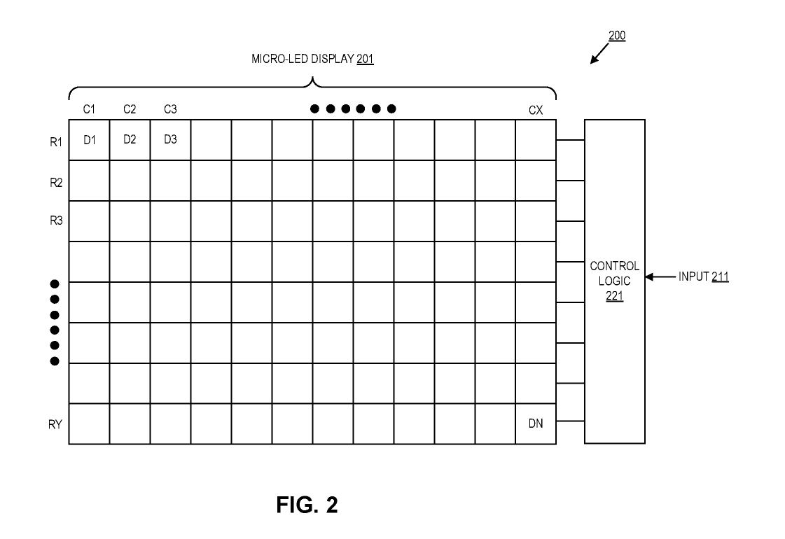

FIG. 2 illustrates a functional block diagram of a micro-LED display system 200 including the LED of FIG. 1 (e.g., LED 100), in accordance with an embodiment of the disclosure. Micro-LED display system 200 includes: micro-LED display 201, control logic 221, and input 211. In one embodiment, micro-LED display 201 is a two-dimensional array including a plurality of LEDs (e.g., D1, D2 . . . , DN) where on or more of LEDs (D1, D2 . . . , DN) may include LED 100. As illustrated, diodes are arranged into rows (e.g., rows R1-RY) and columns (e.g., columns C1-CX) to project image light and form an image on micro-led display 201. However, it should be noted that the rows and columns do not necessarily have to be linear and may take other shapes depending on use case. The LEDs in micro-LED display 201 may be color LEDs arranged into pattern where sub-groups of LED's (corresponding to single image pixels) include red, green, and blue LEDs. The red, green, and blue LEDs in the sub-sub group may be activated at different times and with different intensities such that the viewer sees colors other than red, green, and blue. Alternatively, the LEDs in micro-LED display system 200 may be white LEDs disposed behind a color filter array where sub-groups of LED's are disposed behind a group of red, green, and blue color filters. LEDs in the sub-sub group may be activated at different times and intensities such that the viewer sees colors other than the red, green, and blue provided by the color filters. Further, micro-LED display system 200 may display a static image or may display an active image depending on the data received from control logic 221. In one embodiment, a single diode can range in size from nanometer to micron scale, but more specifically 1-10 μm.

In one embodiment, micro-led display 201 is controlled by control logic 221 coupled to the plurality of LEDs. Control logic 221 may include a processor (or microcontroller), switching power supply, etc. The processor or microcontroller may control individual LEDs in micro-led display 201, or control groups of mico-LEDs.

In the depicted embodiment, micro-led display system 200 includes input 211. Input 211 may include user input via buttons, USB port, wireless transmitter, HDMI port, video player, etc. Input 211 may also include software installed on control logic 221 or data received from the internet or other source.

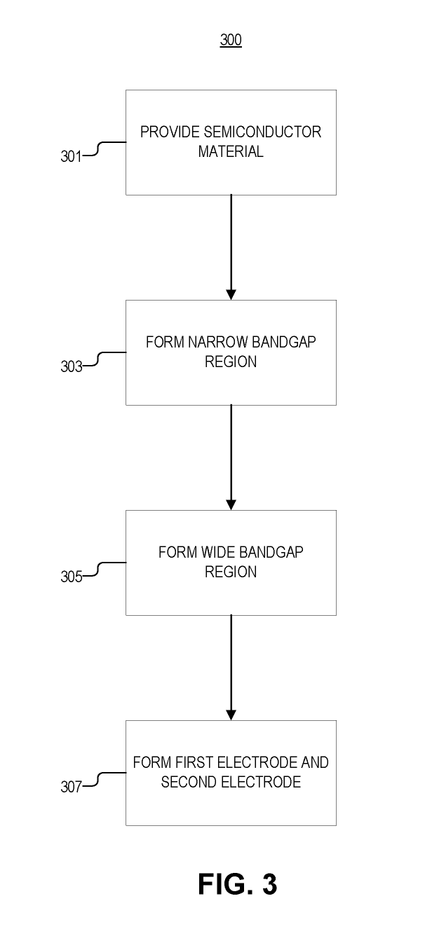

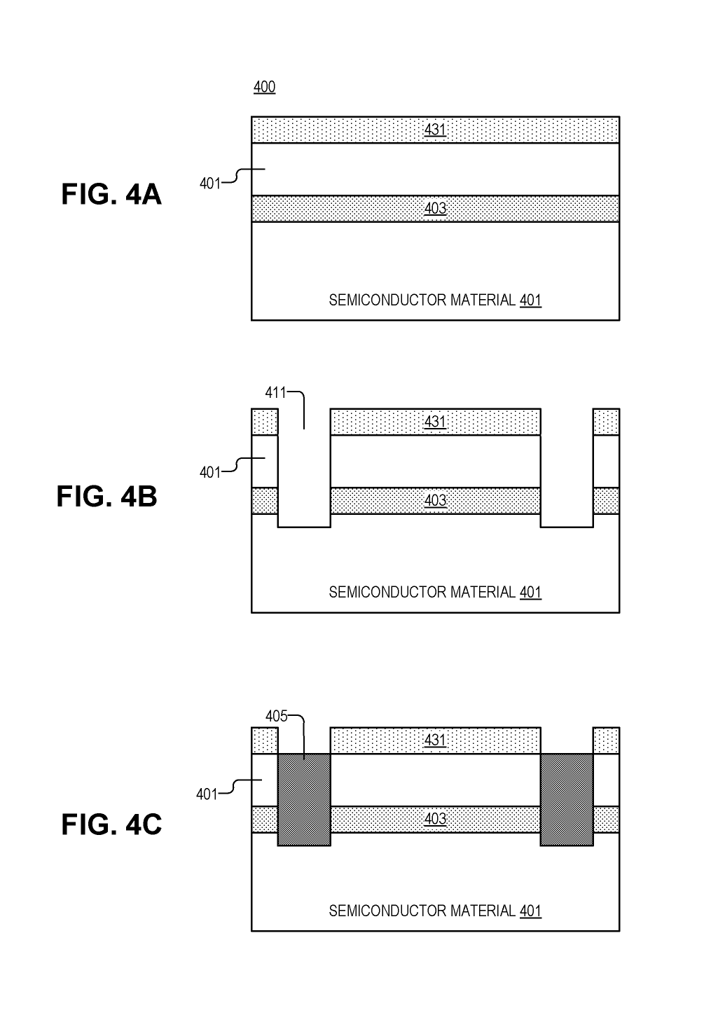

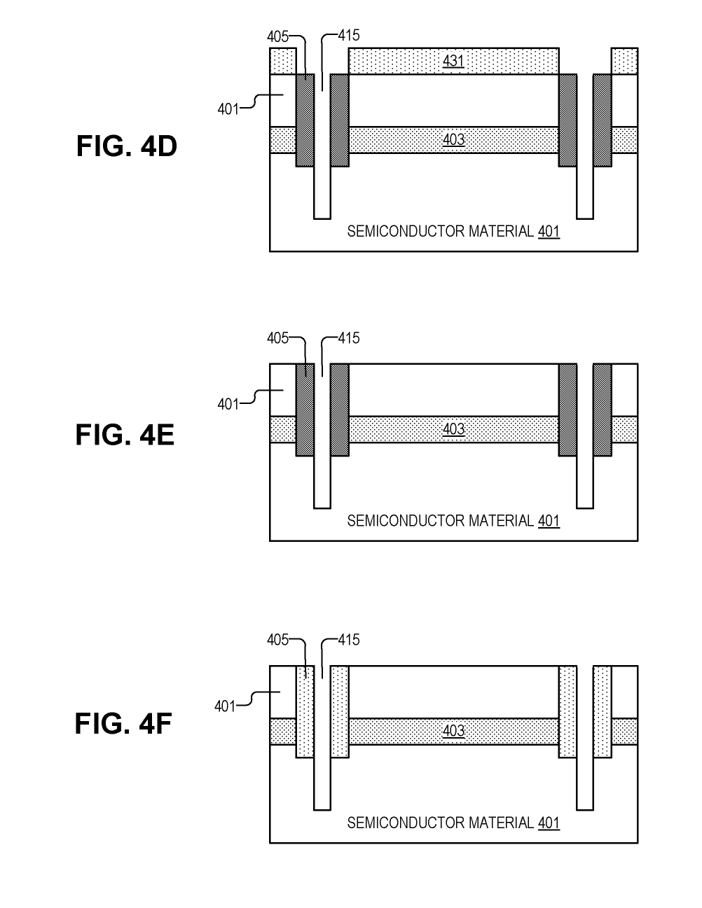

FIG. 3 is a flow chart describing a method of fabricating an LED, in accordance with several embodiments of the disclosure. FIG. 3 is a generic method encompassing the embodiments depicted in FIGS. 4-7. The order in which some or all of process blocks 301-307 appear in process 300 should not be deemed limiting. Rather, one of ordinary skill in the art having the benefit of the present disclosure will understand that some of the process 300 may be executed in a variety of orders not illustrated, or even in parallel. Further, FIGS. 3-7 depict only part of the LED fabrication process and omit steps in order to prevent obscuring certain aspects.

Process block 301 depicts providing a semiconductor material. Semiconductor material may include a single group four element (e.g., C, Si, Ge, Sn, etc.), or may include a compound with group 2 elements (Be, Mg, Ca, Sr, etc.), group 3 elements (B, Al, Ga, In, etc.), group four elements, group 5 elements (N, P, As, Sb, etc.), group 6 elements (O, S, Se, Te, etc.) or any other suitable composition. Example compounds include: AlGaInP, AlGaN, AlGaInN, Al(GaIn)AsP, AlAs, GaAs, GaAsP, GaP, GaN, GaAlAs, InGaN, SiC, ZnO or the like. It is worth noting that these elements/compounds may be used in any semiconductor material, wide bandgap region, and narrow bandgap region described in this disclosure. Additionally, semiconductor material or other pieces of device architecture may be coated with phosphor to create a phosphor-based or phosphor-converted LEDs.

Process block 303 depicts, forming a narrow bandgap region in the semiconductor material. The narrow bandgap region may be one part of the active region and may be disposed in the middle of the active region. As will be discussed in greater detail, narrow bandgap region may be fabricated either by choosing a narrow bandgap semiconductor material such as AlInGaP, or may be achieved through the principals of quantum confinement (e.g., building heterostructures to induce energy barriers).

Process block 305 shows forming a wide bandgap region which is part of the active region. Wide bandgap region has a wider bandgap than the narrow bandgap region and is disposed along the periphery of the active region. This may inhibit charge from reaching a surface of the semiconductor material. In one embodiment, the narrow bandgap region is disposed in the middle of the wide bandgap region. Wide bandgap region may be fabricated by choosing a wide bandgap semiconductor material or through the principals of quantum confinement. In one embodiment, wide bandgap region may have a decreased density of states relative to the narrow bandgap region.

Process block 307 shows forming a first electrode and a second electrode. In the illustrated embodiment, first electrode and second electrode may be disposed on opposite sides of the semiconductor material; however, in a different embodiment, electrodes may be disposed in other locations on the device. In one embodiment, electron/hole blocking layers may be included between the semiconductor material and the first electrode and/or second electrode. However, electron/hole blocking layers may be disposed in the bulk semiconductor material. Further, other forms of surface modification may be used to decrease contact resistance between the semiconductor material and electrodes such as self-assembly or the like.

FIGS. 4A-4F illustrate a method 400 of fabricating an LED, in accordance with an embodiment of the disclosure. The order in which some or all of FIGS. 4A-4F appear in method 400 should not be deemed limiting. Rather, one of ordinary skill in the art having the benefit of the present disclosure will understand that some of the method 400 may be executed in a variety of orders not illustrated, or even in parallel.

FIG. 4A depicts providing semiconductor material 401 including narrow bandgap region 403 disposed in the center of semiconductor material 401. However, in another embodiment, narrow bandgap region 403 may be disposed closer to the top or bottom surface of semiconductor material 401. Also depicted is dielectric layer 431 disposed on a surface of the semiconductor material 401. In one example, dielectric layer 431 has a material composition such that in subsequent semiconductor growth steps, deposited material selectively binds to semiconductor material 401 and not dielectric layer 431. Dielectric layer 431 may include SiOₓ, AlOₓ, SiNₓ, or other non-selective dielectric materials.

FIG. 4B depicts etching trenches 411 in semiconductor material 401, where narrow bandgap region 403 is bordered by trenches 411. In the depicted embodiment, trenches 411 extend from a surface of semiconductor material 401 through narrow bandgap region 403. However in a different embodiment, trenches 411 may only extend to the bottom of narrow bandgap region 403. Etching trenches 411 may be achieved via a wet or dry etch. Although not depicted, in order to form the desired trench structure an etch mask or photoresist (either negative or positive) may be applied to the surface of dielectric layer 431. Part of the etch mask/photoresist is then developed/removed and the etchant is applied. However, in another embodiment, the pattern may be formed via imprint lithography.

FIG. 4C shows depositing wide bandgap region 405 in trenches 411 where the wide bandgap region 405 is conformal with walls of the trenches 411. In the depicted embodiment, the wide bandgap region 405 extends from the bottom of trench 411 to the surface of semiconductor material 401.

FIG. 4D depicts etching trenches 415 in wide bandgap region 405. Trenches 415 extend through wide bandgap region 405 from the top surface of semiconductor material 401. As previously stated trenches 415 may be patterned with either negative or positive photoresists and material may be removed via a wet or dry etch. It is worth noting that narrow bandgap region 403 is disposed in the center of the trenches 411 containing wide bandgap region 405 to prevent charge from reaching the surface of semiconductor material 401.

FIG. 4E shows removal of dielectric layer 431. In one embodiment this may be achieved via chemical mechanical polishing (CMP) or a selective etch.

FIG. 4F depicts oxidizing the wide bandgap region. In the depicted embodiment, wide bandgap region 405 is oxidized in its entirety. However, in other embodiments, only part wide bandgap region 405 is oxidized. In some embodiments, the resultant oxide may still be semiconducting.

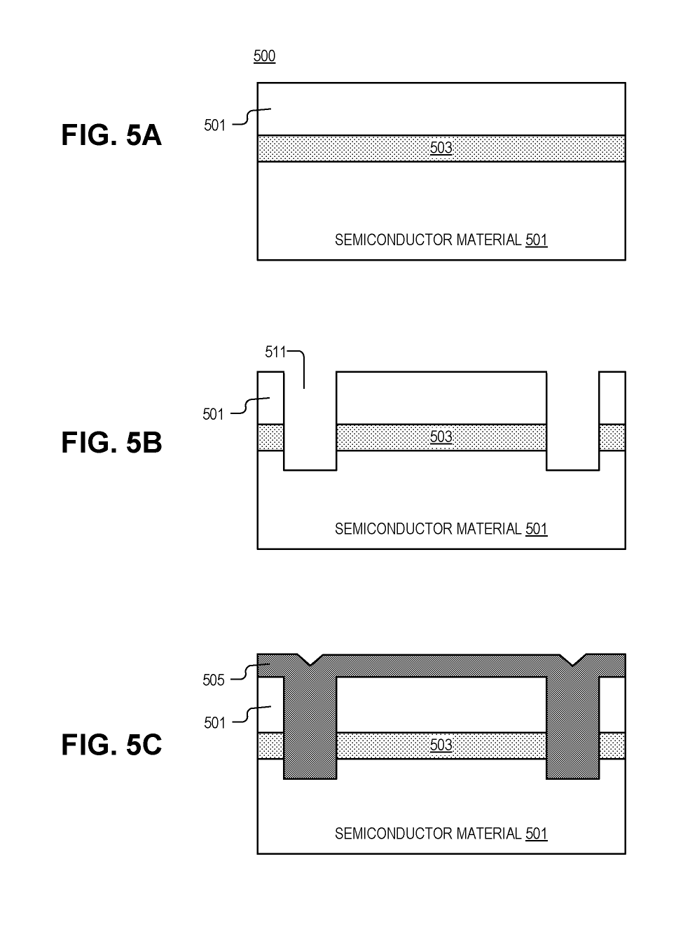

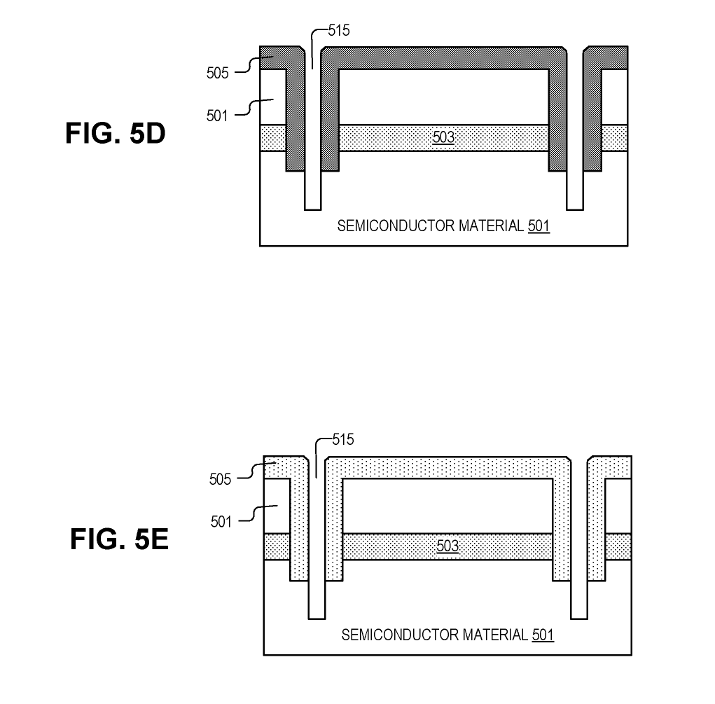

FIGS. 5A-5E illustrate a method 500 of fabricating an LED, in accordance with an embodiment of the disclosure. The order in which some or all of FIGS. 5A-5E appear in method 500 should not be deemed limiting. Rather, one of ordinary skill in the art having the benefit of the present disclosure will understand that some of the method 500 may be executed in a variety of orders not illustrated, or even in parallel.

FIG. 5A depicts providing semiconductor material 501 including narrow bandgap region 503. It is worth noting that unlike FIG. 4A there is no dielectric layer (e.g., dielectric layer 431) disposed on the surface of semiconductor material 501.

FIG. 5B (like FIG. 4B) depicts etching trenches 511 in semiconductor material 501, such that narrow bandgap region 503 is bordered by trenches 511. Etching trenches 511 may be achieved via a wet or dry etch. Although not depicted, in order to form the desired trench structure, a photoresist (either negative or positive) may be deposited onto the surface of semiconductor material 501. Part of the photoresist is then developed/removed and the etchant is applied. In the depicted embodiment, trenches 511 extend form a surface of semiconductor material 501 through narrow bandgap region 503. Although only a two-dimensional image of method 500 is shown, trenches 511 may encircle narrow bandgap region 503 in whole or part.

FIG. 5C shows wide bandgap region 505 being deposited on the surface of semiconductor material 501 and in trenches 511. In the depicted embodiment, wide bandgap region 505 is conformal with the sidewalls of the trenches 511 and the surface of semiconductor material 501. Wide bandgap region 505 may be deposited via thermal evaporation, chemical vapor deposition, molecular beam epitaxy, atomic layer deposition, or the like.

FIG. 5D illustrates etching trenches 515 through wide bandgap region 505 and into semiconductor material 501. Thus, wide bandgap region 505 is disposed on the sides of the active region to prevent charge transfer to the surface of the LED.

FIG. 5E depicts oxidation of wide bandgap region 505. In the depicted embodiment, wide bandgap region 505 is fully oxidized; however, in other embodiments not depicted wide bandgap region 505 may only be partially oxidized. In one embodiment, the portion of wide bandgap region 505 disposed on the surface of semiconductor material 501 may be removed via chemical mechanical polishing or anisotropic etch.

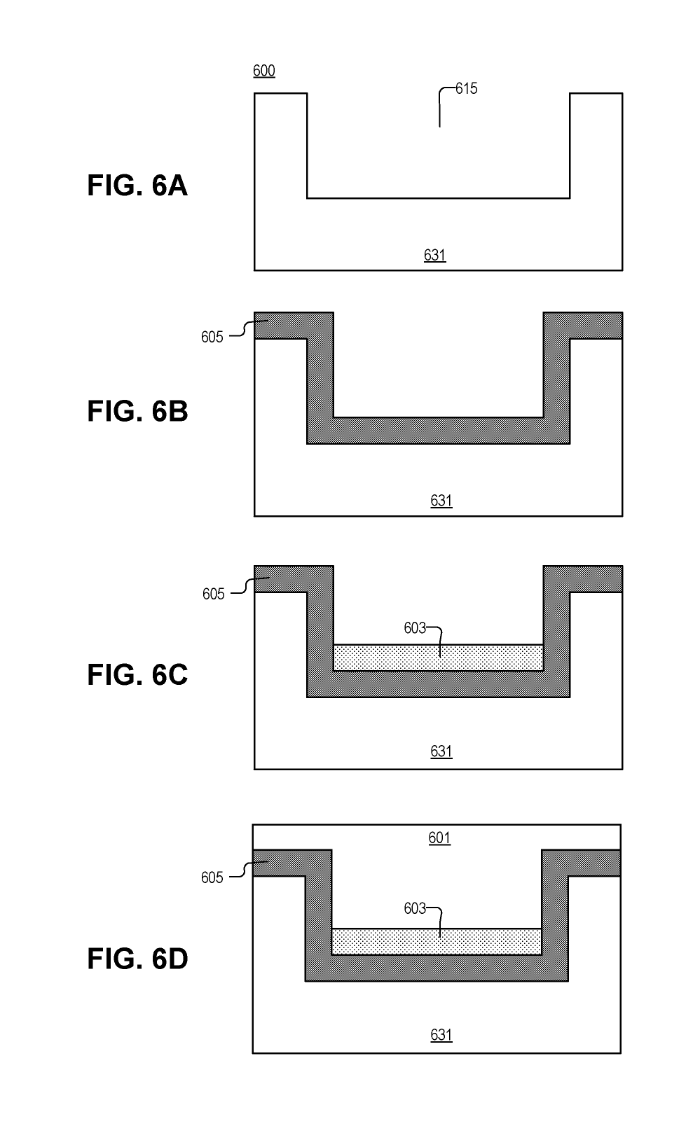

FIGS. 6A-6D illustrate a method 600 of fabricating an LED, in accordance with an embodiment of the disclosure. The order in which some or all of FIGS. 6A-6D appear in method 600 should not be deemed limiting. Rather, one of ordinary skill in the art having the benefit of the present disclosure will understand that some of the method 600 may be executed in a variety of orders not illustrated, or even in parallel.

FIG. 6A shows etching a trench 611 in a substrate 631. Trench 611 will template the rest of the LED device active region.

FIG. 6B depicts depositing wide bandgap region 605 in the trench 611, and wide bandgap region 605 is conformal with sidewalls of trench 611 and the surface of substrate 631.

FIG. 6C shows depositing narrow bandgap region 503 into the trench 611. Narrow bandgap region 603 spans the width of the trench 611 and is conformal with wide bandgap region 605.

FIG. 6D shows depositing semiconductor material 601 into the trench 611, and wide bandgap region 605 is conformal with lateral edges of the semiconductor material 601.

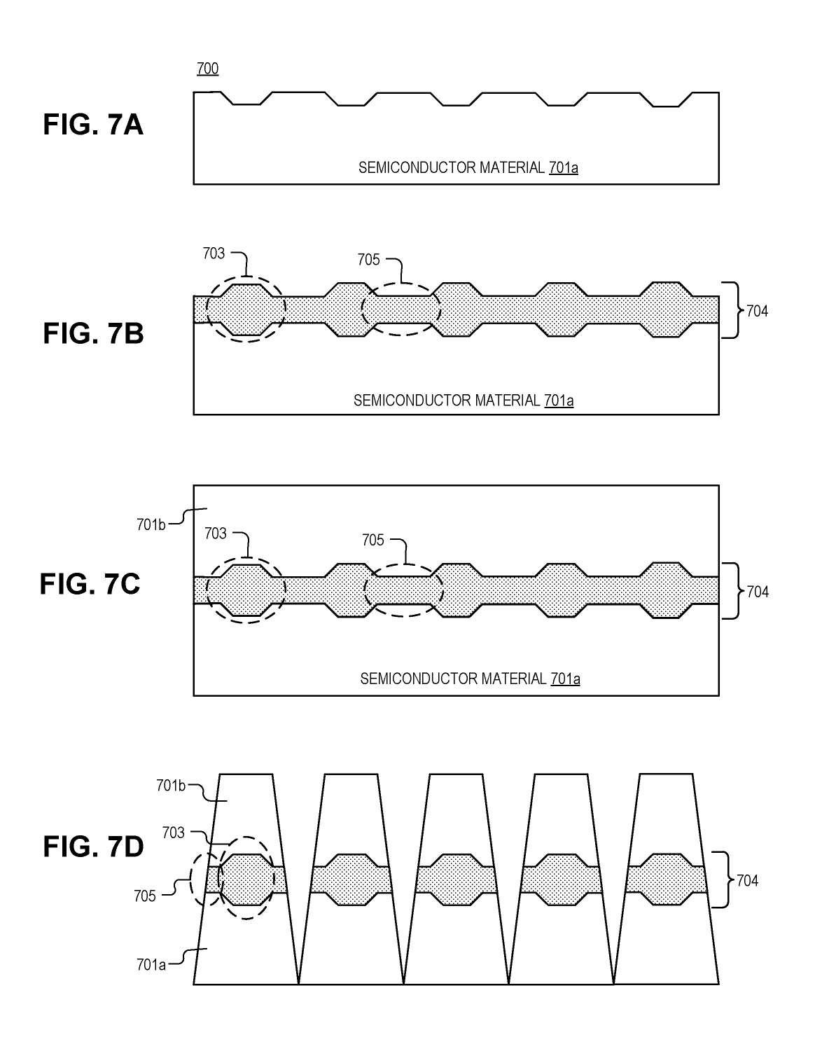

FIGS. 7A-7D illustrate a method 700 of fabricating an LED, in accordance with an embodiment of the disclosure. The order in which some or all of FIGS. 7A-7D appear in method 700 should not be deemed limiting. Rather, one of ordinary skill in the art having the benefit of the present disclosure will understand that some of the method 700 may be executed in a variety of orders not illustrated, or even in parallel.

FIG. 7A depicts providing a first semiconductor material 701a. In the depicted embodiment, trenches are formed in a surface of the first semiconductor material 701a. This may be achieved by etching or by patterning an underlying substrate. The trenches are defined by low points in the first semiconductor material 701a separated by high points in the first semiconductor material 701a.

FIG. 7B shows depositing an active region 704 on first semiconductor material 701a, and active region 704 includes wide bandgap region 705 and narrow bandgap region 703. Wide bandgap region 705 has a wider bandgap than narrow bandgap region 703. In the depicted embodiment, wide bandgap region 705 and narrow bandgap region 703 include the same material composition. Narrow bandgap region 703 includes a bulk semiconductor, and wide bandgap region 705 includes a spatially confined semiconductor with a lower density of states than the bulk semiconductor. In the depicted embodiment, active region 704 is thicker proximate to the low points in first semiconductor material 701a, and thinner proximate to the high points in first semiconductor material 701a. Wide bandgap region 705 is disposed in active region 704 proximate to the high points in first semiconductor material 701a, and narrow bandgap region 703 is disposed in active region 704 proximate to the low points in first semiconductor material 701a. In this configuration, wide bandgap region 705 has a lower density of states because it is not thick enough to have the electronic properties of a “bulk” semiconductor. Thus, the lowest energy state of narrow bandgap region 703 is lower than the lowest energy state of wide bandgap region 705.

In one embodiment, the growth of active region 704 is achieved by etching first semiconductor material 701a to expose different crystal faces of first semiconductor material 701a. This may facilitate preferential growth of active region 704 in some places on first semiconductor material 701a, while slowing growth in other places on semiconductor material 701a. Alternatively, the difference in bandgap between wide bandgap region 705 and narrow bandgap region 703 may be caused by the orientation/atomic configuration of the crystal growth plane of the semiconductor crystal in active region 704. In other words, the semiconductor crystal in active region 704 could be grown to have a variable bandgap with respect to spatial position depending on the crystallographic faces exposed on semiconductor material 701a and the growth conditions employed. In another embodiment, compositional variations in active region 704 (driven by the morphology of, or a pattern on, first semiconductor material 701a) may lead to the difference in bandgap between wide bandgap region 705 and narrow bandgap region 703. In one embodiment, active region 704 may include AlGaInP.

FIG. 7C illustrates depositing a second semiconductor material 701b on active region 704, where active region 704 is disposed between the first semiconductor material 701a and the second semiconductor material 701b. In one embodiment, first semiconductor material 701a and second semiconductor material 701b include the same material composition. However, in a different embodiment, first semiconductor material 701a and second semiconductor material 701b may include different material compositions.

FIG. 7D shows cutting semiconductor material 701 into discrete LEDs. This cutting process may involve sectioning semiconductor material 701 via mechanical force (e.g., bladed wafer dicer) or may involve sectioning semiconductor material 701 via optical means (e.g., laser wafer dicer). Alternatively, semiconductor material 701 may be sectioned via etching or chemical force. Although only FIG. 7D depicts cutting semiconductor material 701 into discrete LEDs, all other embodiments may include separating the individual LEDs.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

1. A light emitting diode (LED), comprising:
a semiconductor material including an active region, wherein the active region is disposed in the semiconductor material to produce light in response to a voltage applied across the semiconductor material, and wherein the active region includes:
a wide bandgap region disposed adjacent to lateral edges of the LED, wherein the wide bandgap region is disposed to inhibit charge transfer from a central region of the LED to the lateral edges of the LED; and
a narrow bandgap region disposed in the central region with the wide bandgap region disposed about the narrow bandgap region, wherein the narrow bandgap region produces the light, and wherein the narrow bandgap region has a narrower bandgap than the wide bandgap region.

2. The LED of claim 1, wherein the wide bandgap region and the narrow bandgap region have different elemental compositions.

3. The LED of claim 2, wherein the wide bandgap region includes Al(GaIn)AsP or AlAs.

4. The LED of claim 1, wherein at least part of the wide bandgap region is oxidized.

5. The LED of claim 1, wherein the wide bandgap region and the narrow bandgap region have the same elemental composition, and wherein the narrow bandgap region has a higher density of states than the wide bandgap region.

6. The LED of claim 1, further comprising trenches disposed in the semiconductor material, wherein the trenches extend from a surface of the semiconductor material through the narrow bandgap region, and wherein the wide bandgap region is disposed in the trenches to surround the narrow bandgap region.

7. The LED of claim 1, further comprising a substrate including a trench disposed in the substrate, wherein the wide bandgap region is conformally disposed on walls of the trench, and wherein the semiconductor material is disposed in the trench.

8. The LED of claim 1, further comprising a first electrode and a second electrode, wherein the semiconductor material is disposed between the first electrode and the second electrode.

9. The LED of claim 8, wherein the first electrode is transparent.

10. The LED of claim 1, further comprising a plurality of LEDs including the LED, wherein the plurality of LEDs is arranged into an array including rows and columns.

11. The LED of claim 10, further comprising control logic coupled to the plurality of LEDs, wherein the control logic controls operation of the plurality of LEDs.

12.-23. (canceled)
